(19) United States
(12) Patent Application Publication
(10) Pub. No.: US 2014/0247056 A1
(43) Pub. Date: Sep. 4, 2014

(54) Method and Apparatus for Calibrating Voltage Transformer Serial Addition

(71) Applicants: Feng Zhou, Hongshan (CN); Min Lei, Hongshan (CN); Min Li, Hongshan (CN); Shuhan Zhang, Hongshan (CN); Yueren Wang, Hongshan (CN)

(72) Inventors: Feng Zhou, Hongshan (CN); Min Lei, Hongshan (CN); Min Li, Hongshan (CN); Shuhan Zhang, Hongshan (CN); Yueren Wang, Hongshan (CN)

(73) Assignee: CHINA ELECTRIC POWER RESEARCH INSTITUTE, Beijing (CN)

(21) Appl. No.: 14/130,911

(22) PCT Filed: Aug. 30, 2011
(86) PCT No.: PCT/CN2011/079083

§ 371 Date: May 12, 2014

(30) Foreign Application Priority Data
Jul. 5, 2011 (CN) 201110185690.9

(51) Int. Cl. G01R 31/02

(52) U.S. Cl. CPC G01R 31/027
USPC 324/547

(57) ABSTRACT

A series summation-calibrating device based on a semi-insulating voltage transformer includes a symmetrical high voltage test power supply, a three-port serial voltage transformer, a semi-insulating voltage transformer and an error measuring apparatus. The present invention is characterized by: a complete set of equipment for measuring the traceability of power frequency voltage ratio can be manufactured; calibrating the line according to the serial addition based on the semi-insulating voltage transformer; measuring the relative error between the three-port serial voltage transformer and the semi-insulating voltage transformer; and mathematically processing the measuring result to obtain the voltage coefficient curve of the semi-insulating voltage transformer error. The method is easy to operate without being restricted by voltage level, and can establish, from a low voltage of 10V to a high voltage of 1,000V, a standard power frequency voltage ratio measurement system serving as a measurement standard at the national or provincial/ministerial level.

### CROSS REFERENCE OF RELATED APPLICATION

This is a non-provisional application that claims the benefit of priority under 35 U.S.C. §119 to a non-provisional application, application number PCT/CN2011/079083, filed Aug. 30, 2011.

### BACKGROUND OF THE PRESENT INVENTION

1. Field of Invention

The present invention relates to an error calibrating method for a voltage transformer and a calibrating apparatus, which belongs to the measurement and precision test field of science and technology, and more particularly to a series summation calibration method for a voltage transformer and an apparatus for the series summation calibration method.

2. Description of Related Arts

In order to ensure a fair, equitable accurate and standardized energy metering and guarantee the multiple needs of electricity generation enterprises, power transmission enterprises and power suppliers for definiteness. A transformer for measuring must be forcedly and regularly calibrated in accordance with the relevant provisions of the Metrology Law of the People's Republic of CHINA, and the calibration has to be carried out by standard instruments of measurement for providing standard values.

As an important power frequency voltage proportional measurement instrument being easy to use and having stable values, the standard voltage transformer mainly has three value reproduction methods: reference potential method, digital-analog method and voltage summation method. In 1953, German Physikalisch-Technische Bundesanstalt (PTB) disclosed a voltage transformer parallel-series summing circuit (See “voltage transformer error absolute calibration method”, West German electrical technology journal, ETZ-A75 S805) and established a 120 kV electromagnetic frequency voltage proportionality standard in German, which has strict requirements regarding voltage stability and symmetry of the center tap of the supply transformer and needs a precise AC stabilized voltage supply to control harmonic distortion below 0.1% and joining a voltage regulating device in high-potential to ensure the symmetry of the intermediate potential. In addition, the secondary circuit can only be connected in parallel and two sets of differential measuring device are needed to adjust respectively the balance in each of the high-voltage circuit and low voltage circuits, which is very difficult to perform and has not been popularized in an international context. In 1989, the national high voltage metering station (China) invented the series summing circuit based on the fully insulated voltage transformer (See Chinese patent 90100301.8, the principle of the circuit is shown in FIG. 1), and the 110 kV frequency voltage proportional standard device of China, established in 1992. This device has good ability to trace the source and ability for self-calibration, which forms a self-calibrating system.

However, there still exists the voltage coefficient estimation during use of the method, and because of an imperfect shield, when the shield potential changes, a leakage current flows through the field winding during calibration, which substantially results in an inaccuracy of the standard device. And the fact that the circuit is based on the fully-insulated voltage transformer determines that the applicable voltage level of the circuit is not higher than 220 kV and cannot meet the application of the higher voltage level.

### SUMMARY OF THE PRESENT INVENTION

The object of the present invention is as follows: providing an series summation calibrating method and apparatus based on a semi-insulating voltage transformer, which is easy to operate, unlimited by the voltage level and can be used for measuring voltage transformer changes in error to achieve the purpose of value transfer from a low voltage level voltage transformer to a high voltage level voltage transformer.

The technical solution of the present invention is: a series summation calibrating apparatus for a voltage transformer, which comprises a symmetry high-voltage test power supply, a series voltage transformer having three-ports, a semi-insulating voltage transformer, an error measuring device and a plurality of connecting wires, wherein said symmetry high-voltage test power supply's output is respectively communicated with an input of said series voltage transformer having three-ports and an input of said semi-insulating voltage transformer, wherein said symmetry high-voltage test power supply can not only produce an independent voltage, but also generate symmetry voltages, which is used for generating and changing a high-voltage power supply for calibrating; wherein output signals from said series voltage transformer having three-ports and said semi-insulating voltage transformer are received by said error measuring device, wherein said error measuring device is used for measuring a voltage error of a voltage U₂ of an output of said series voltage transformer having three-ports, referencing a voltage U₃ of an output of said semi-insulating voltage transformer.

The mentioned series summation calibrating apparatus for a voltage transformer, wherein said series voltage transformer has three-ports comprising an upstream structure and a downstream structure, wherein a high-voltage side of each of the upstream structure and the downstream structure is connected with a corresponding low-voltage side of each of the upstream structure and the downstream structure in series, and a secondary circuit of the upstream structure is configured with a high-voltage isolating unit, wherein an input port of the upstream structure and an input port of the downstream structure can be independently and respectively applied on a voltage, or they are simultaneously applied on a voltage.

A series summation calibrating method for a voltage transformer, which employs the mentioned series summation calibrating apparatus for a voltage transformer that comprises the following steps:

1) Applying a half voltage 0 on a port of an upstream structure of the series voltage transformer having three-ports and applying a half voltage U/2 on a port of a downstream structure of the series voltage transformer having three-ports via the symmetry high-voltage test power supply, wherein the error measurement is ε1;

2) Applying a half voltage U/2 on a port of an upstream structure of the series voltage transformer having three-ports and applying a half voltage 0 on a port of an downstream structure of the series voltage transformer having three-ports via the symmetry high-voltage test power supply, wherein the error measurement is ε2;

3) Applying a half voltage U/2 on a port of an upstream structure of the series voltage transformer having three-ports and applying a half voltage U/2 on a port of an downstream structure of the series voltage transformer having three-ports via the symmetry high-voltage test power supply, wherein the error measurement is ε3;

Further, letting respectively the error measurements of the semi-insulating voltage transformer under the conditions of a half voltage U/2 and a total voltage U be γ and γ′, and figuring the error change values of the semi-insulating voltage transformer under the conditions of a half voltage U/2 and a total voltage U out by a formula of

$${γ}^{′} - γ = \frac{ɛ 2 + ɛ 2}{2} - ɛ 3 ,$$

and then obtaining synthetically a voltage coefficient curve of the semi-insulating voltage transformer by an interpolation method.

The present invention has advantages that: 1. The series summation calibrating method and apparatus based on a semi-insulating voltage transformer employ a semi-insulating voltage transformer as a main standard, which has a higher accuracy and a higher voltage level and is more in tune with the fact that the high voltage transformer in field of production have a semi-insulating structure, compared with a fully-insulating voltage transformer; 2. The series summation calibrating method and apparatus based on a semi-insulating voltage transformer is in coordination with the proportionality and superposition of linear circuits, and it is only needed to change a power supply excitation state of the linear circuits during operation, wherein the uncertainty of measurement may be minimized by eliminating shielding leakage and an impact applied on the calibrating result and resulting from stray parameters, utilizing the voltage superposition principle; and, 3. The circuit may be used for calibrating the error measurement of a semi-insulating voltage transformer having a proper parameter and has a good openness.

### BRIEF DESCRIPTION OF THE DRAWINGS

FIG. 1 is a schematic diagram of a series summation circuit for a conventional voltage transformer.

FIG. 2 is a principle block diagram of a series summation calibrating apparatus based on a semi-insulating voltage transformer according to the embodiment of the present invention.

FIG. 3 is a flow chart of a series summation calibrating method based on a semi-insulating voltage transformer according to the embodiment of the present invention.

### DETAILED DESCRIPTION OF THE PREFERRED EMBODIMENT

Referring to the drawings and embodiments of the present invention, the present invention is illustrated as follow.

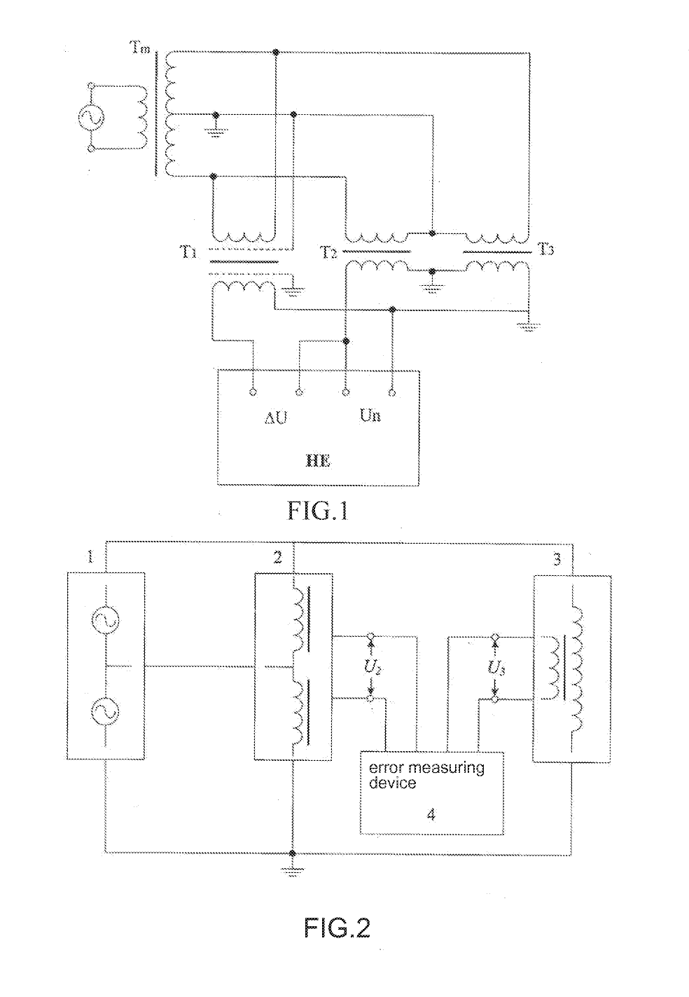

FIG. 1: Tm-bipolar testing transformer, T₁-fully-insulating and shielding voltage transformer, T₂-standard voltage transformer, HE-error measurement device, ΔU-differential voltage end of a circuit, Un-reference voltage end of a circuit.

FIG. 2: 1—a symmetry high-voltage test power supply, 2—a series voltage transformer having three-ports, 3—a semi-insulating voltage transformer, 4—a an error measuring device, U₂—voltage of an output end of a series voltage transformer having three-ports, U₃—a voltage of an output end of a semi-insulating standard voltage transformer, K₁ and K₂—a switching device for changing an excitation state of a series voltage transformer having three-ports.

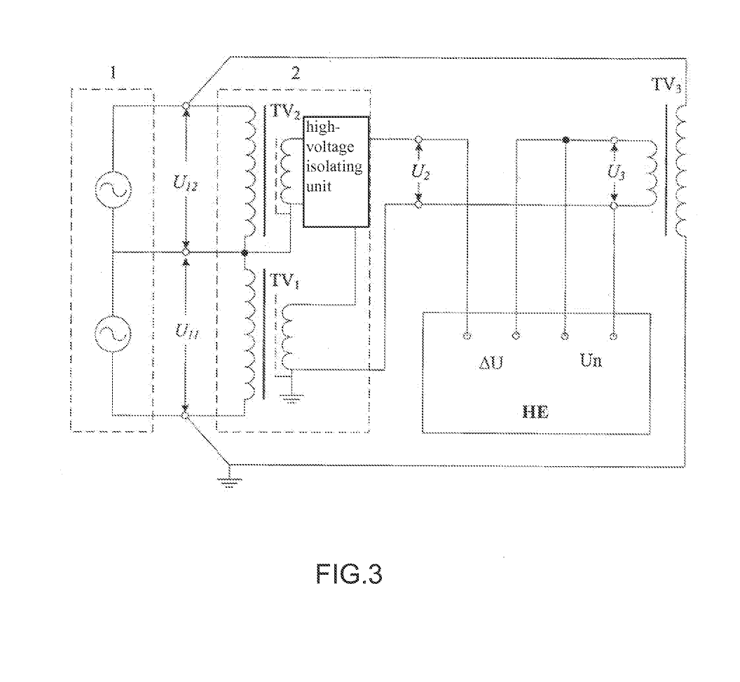

FIG. 3: TV₁—a downstream structure of a series voltage transformer having three-ports, TV₂—an upstream structure of a series voltage transformer having three-ports, TV₃—a semi-insulating voltage transformer, U₁₁—voltage of an input port of a downstream structure of a series voltage transformer having three-ports, U₁₂—voltage of an input port of an upstream structure of a series voltage transformer having three-ports.

The diagram of the series summation calibrating method and device based on a semi-insulating voltage transformer according to the embodiment of the present invention to is as shown in FIG. 2, wherein the corresponding circuit comprises: 1. the series voltage transformer having three-ports, 2. the semi-insulating voltage transformer TV₃ and the error measuring device, wherein the series voltage transformer 2 having three-ports comprises the downstream structure TV₁ and the upstream structure TV₂, the high-voltage side of each of the downstream structure TV₂ and the upstream structure TV₂ and is connected with the corresponding low-voltage side of each of the downstream structure TV₂ and the upstream structure TV₂ in series, and the secondary circuit of the upstream structure TV₂ is configured with the high-voltage isolating unit for insulating a potential difference between the secondary circuit of the upstream structure TV₂ and a secondary circuit of the downstream structure TV₁.

Letting rated voltage ratios among TV₁, TV₂ and TV₃ be K, and the errors under the same excitation voltage be respectively α, β and γ. Letting the response of the voltage U₂ of an output port of a series voltage transformer 2 having three-ports to the voltage U₁₁ of the input port be U₂₁, wherein

$${U}_{21} = \frac{{U}_{11}}{K} ( 1 + α ) ,$$

the response to the voltage U₁₂ of the input port be U₂₂, wherein

$${U}_{22} = \frac{{U}_{12}}{K} ( 1 + β ) ,$$

the response of the voltage U₃ of an output port of a semi-insulating voltage transformer TV3 to the voltage U₁₁ of the input port be U₃₁, wherein

$${U}_{31} = \frac{{U}_{11}}{K} ( 1 + γ ) ,$$

the response to the voltage U₁₂ of the input port be U₃₂, wherein

$${U}_{32} = \frac{{U}_{12}}{K} ( 1 + γ ) ,$$

When the voltage transformer TV1 works only in U₁₁, the voltage transformer TV, works only in U₁₂, and which do not show non-linear, so the series circuits of TV1 and TV₂ meet the conditions of linear circuits, and according to the superposition principle, the following are given:

$${\dot{U}}_{2} = {\dot{U}}_{21} + {\dot{U}}_{22} = \frac{{U}_{11}}{K} ( 1 + α ) + \frac{{U}_{12}}{K} ( 1 + β )$$

Letting the error of TV3 working in U₁₁+U₁₂ be γ′, so it is given:

$${U}_{3} = \frac{{U}_{11} + {U}_{12}}{K} ( 1 + {γ}^{′} )$$

When the outputs of the symmetry high-voltage test power supply 1 are respectively U₁₁, U₁₂ and U₁₁+U₁₂ (taking into account the symmetry of the test power, U₁₁≈U₁₂), the proportional errors of the series voltage transformer 2 and the semi-insulating voltage transformer TV₃ are respectively measured as ε1, ε₂ and ε₃ according to the circuit shown in FIG. 2, based on the definition of the transformer error, it is given:

$$\begin{matrix}{ɛ}_{1} = \frac{{U}_{21} - {U}_{31}}{{U}_{31}} = \frac{1 + α}{1 + γ} - 1 \approx α - γ & ( 1 ) \\ {ɛ}_{2} = \frac{{\dot{U}}_{22} - {\dot{U}}_{32}}{{\dot{U}}_{32}} = \frac{1 + β}{1 + γ} - 1 \approx β - γ & ( 2 ) \\ {ɛ}_{3} = \frac{{U}_{2} - {U}_{3}}{{U}_{3}} = \frac{( 1 + α ) / 2 + ( 1 + β ) / 2}{1 + {γ}^{′}} - 1 \approx \frac{α + β}{2} - {γ}^{′} & ( 3 )\end{matrix}$$

Synthesizing the formulas of (1), (2) and (3), we can get:

$${γ}^{′} - γ = \frac{{ɛ}_{1} + {ɛ}_{2}}{2} - {ɛ}_{1} \qquad ( 4 )$$

Thus, the error changes of TV₃ in the voltages U/2 and U can be determined via three times measurements, a correlation curve between the error of TV₃ and the voltage is obtained via an interpolation method. And then, it is only needed to calibrate the error (generally, under 10%˜20% rated voltage) of a single point of the curve for getting an error curve of TV₃ in a full measuring range of voltage. The method can be used for manufacturing a complete set of equipment for tracing to the source of a power frequency voltage proportional value, and establishing a power frequency voltage proportional value system in a range from a low voltage 10V to a high voltage 1000 kv, which can serve as a national or provincial and ministerial measurement standard.

What is claimed is:

1. A series summation calibrating device for a voltage transformer, comprising a symmetry high-voltage test power supply, a series voltage transformer having three-ports, a semi-insulating voltage transformer, an error measuring device, and a plurality of connecting wires, wherein an output of said symmetry high-voltage test power supply is respectively communicated with an input of said series voltage transformer having three-ports and an input of said semi-insulating voltage transformer, wherein said symmetry high-voltage test power supply does not only output an independent voltage, but also output symmetry voltages, which is used for generating and changing a high-voltage power supply for calibrating, wherein output signals from said series voltage transformer having three-ports and said semi-insulating voltage transformer are received by said error measuring device, wherein said error measuring device is used for measuring a voltage error of a voltage U₂ of an output of said series voltage transformer having three-ports, referencing a voltage U₃ of an output of said semi-insulating voltage transformer.

2. The series summation calibrating device, as recited in claim 1, wherein said series voltage transformer having three-ports comprises an upstream structure and a downstream structure, wherein a high-voltage side of each of the upstream structure and the downstream structure is connected with a corresponding low-voltage side of each of the upstream structure and the downstream structure in series, and a secondary circuit of the upstream structure is configured with a high-voltage isolating unit, wherein an input port of the upstream structure and an input port of the downstream structure can be independently and respectively applied on a voltage, or they are simultaneously applied on a voltage.

3. A series summation calibrating method for a voltage transformer, comprising the steps of:
(a) applying a half voltage 0 on a port of an upstream structure of the series voltage transformer having three-ports and applying a half voltage U/2 on a port of an downstream structure of the series voltage transformer having three-ports via the symmetry high-voltage test power supply, wherein the error measurement is ε1;
(b) applying a half voltage U/2 on a port of an upstream structure of the series voltage transformer having three-ports and applying a half voltage 0 on a port of an downstream structure of the series voltage transformer having three-ports via the symmetry high-voltage test power supply, wherein the error measurement is ε2; and
(c) applying a half voltage U/2 on a port of an upstream structure of the series voltage transformer having three-ports and applying a half voltage U/2 on a port of an downstream structure of the series voltage transformer having three-ports via the symmetry high-voltage test power supply, wherein the error measurement is ε3;
wherein letting respectively an error measurements of said semi-insulating voltage transformer under said conditions of a half voltage U/2 and a total voltage U be γ and γ′, and figuring error change values of said semi-insulating voltage transformer under said conditions of a half voltage U/2 and a total voltage U out by a formula of
$${γ}^{′} - γ = \frac{ɛ 2 + ɛ2}{2} - ɛ 3 ,$$
and then obtaining synthetically a voltage coefficient curve of said semi-insulating voltage transformer by an interpolation method.
